(19) United States
(12) Patent Application Publication
(10) Pub. No.: US 2024/0431033 A1
(43) Pub. Date: Dec. 26, 2024

(54) PACKAGING METHOD AND PACKAGING DEVICE FOR PCBA BOARD

(71) Applicant: KONIG ELECTRONIC TECHNOLOGY CO., LTD, Suzhou, Jiangsu (CN)

(72) Inventor: Jianxiao ZHU, Suzhou, Jiangsu (CN)

(21) Appl. No.: 18/700,317

(22) PCT Filed: Nov. 18, 2021
(86) PCT No.: PCT/CN2021/131465

§ 371 Date: Apr. 11, 2024

(30) Foreign Application Priority Data
Oct. 13, 2021 (CN) 202111194776.8
Oct. 14, 2021 (CN) 202111200265.2
Oct. 19, 2021 (CN) 202111216275.5
Oct. 19, 2021 (CN) 202111216295.2

(51) Int. Cl. H05K 3/00; H05K 3/28

(52) U.S. Cl. CPC H05K 3/0091; H05K 3/284; H05K 3/287; H05K 2203/075; H05K 2203/10; H05K 2203/1366

(57) ABSTRACT

The disclosure discloses a packaging method and a packaging device for a PCBA board. The PCBA board comprises a printed circuit board and an electronic element arranged on the printed circuit board; the maximum height of the electronic element relative to surface of the printed circuit board is less than 1 cm. The packaging method comprising: during glue spraying process, controlling a glue spraying assembly to spray UV glue liquid to a target spraying area of the PCBA board by moving back and forth in a straight line in a horizontal direction. The packaging method for a PCBA board provided by the present disclosure realizes packaging and protection of electronic components by spraying UV glue liquid to an area of the PCBA board that needs protection by the glue spraying assembly.

### CROSS-REFERENCE RELATED REFERENCE

This application is a continuation of PCT/CN2021/131465, filed Nov. 18, 2021 and claims priority of Chinese Patent Application No. 202111194776.8, filed on Oct. 13, 2021 and entitled “Packaging Method for PCBA Board”, the Chinese patent application with the application number 20211,1200265.2, filed on Oct. 14, 2021 and entitled “Packaging Method and Packaging Device for PCBA Board”, the Chinese patent application with the application number 20211,1216295.2, filed on Oct. 19, 2021 and entitled “Packaging Method and Packaging Device for PCBA Board”, the Chinese patent application with the application Ser. No. 20211,1216275.5, filed on Oct. 19, 2021 and entitled “Packaging Method and Packaging Device for PCBA Board”, the entire contents of which are incorporated herein by reference.

### TECHNICAL FIELD

The disclosure relates to the field of circuit board packaging, in particular to a packaging method and a packaging device for a PCBA board.

### BACKGROUND

There are many packaging methods for a PCBA (Printed Circuit Board+Assembly) board, such as packaging methods of spraying three-proof paint on the surface of the circuit board, potting and low pressure injection molding. Each of the above methods has its own advantages and disadvantages: as to direct spraying of three-proof paint, although the operation is simple, convenient and easy to achieve, but can not really protect the circuit board, can not achieve waterproof, shock-proof, take a long time, and the package may fail; as to potting, the operation is complex and has low efficiency, high cost and poor reliability; as to low pressure injection molding, low pressure injection molding equipment is used to complete the packaging of the circuit board through a special mold by adjusting the corresponding injection pressure and time, and in this method, the mold design and production cost is high, and the characteristics of the glue itself has a great impact on the packaging.

### SUMMARY OF THE INVENTION

In view of the above disadvantages of the prior art, one purpose of the present disclosure is to provide a PCBA board packaging device and a PCBA board packaging method suitable for reliable packaging of a PCBA board with low height.

One object of the present disclosure is to provide a PCBA board packaging device and a PCBA board packaging method capable of accurately positioning and packaging part of the PCBA board.

The present disclosure has another object to provide a PCBA board packaging UV glue liquid for a piezoelectric array nozzle to provide reliable protection against electronic elements on the PCBA board.

The present disclosure has a further object to provide a piezoelectric array nozzle to spray UV glue at accurate position of the electronic elements on the PCBA board to achieve pixel-level packaging of the PCBA board.

To achieve at least one of the above objects, the present disclosure adopts the following technical solution:
a packaging method for a PCBA board comprising a printed circuit board and an electronic element arranged on the printed circuit board; the maximum height of the electronic element relative to surface of the printed circuit board is less than 1 cm, the packaging method comprising: during glue spraying process, controlling a glue spraying assembly to spray UV glue liquid to a target spraying area of the PCBA board by moving back and forth in a straight line in a horizontal direction.

As a preferred embodiment, in the packaging method, the glue spraying assembly is positioned above the highest electronic element and the spacing between the glue spraying assembly and the highest electronic element is controlled to be less than 2 mm.

As a preferred embodiment, the spacing between the glue spraying assembly and the highest electronic element is controlled to be less than 1 mm.

As a preferred embodiment, relative height of the glue spraying assembly and the PCBA board is unchanged during the glue spraying process.

As a preferred embodiment, during the glue spraying process, the glue spraying assembly is controlled to move back and forth in a horizontal straight line to spray UV glue liquid to the target spraying area of the PCBA board until the spraying package is completed.

As a preferred embodiment, the packaging method comprises placing the PCBA board horizontally on a working table and controlling the glue spraying assembly to spray glue on the PCBA board on the working table in such a way that a spraying hole is vertically oriented toward the working table.

As a preferred embodiment, the packaging method further comprises: obtaining number of target spraying layers; wherein one spraying layer is formed by one linear one-way movement of the glue spraying assembly, and two spraying layers are formed by one linear round-trip movement.

The glue spraying assembly is controlled to spray UV glue liquid to a target spraying area of the PCBA board by moving back and forth in a straight line in a horizontal direction until the target spraying area reaches the number of target spraying layers.

As a preferred embodiment, the PCBA board has a positioning point; the glue spraying assembly is fixedly provided with a positioning portion for positioning the positioning point; the packaging method comprises:
placing the PCBA board horizontally on a working table; and
moving the glue spraying assembly and controlling the working table to move according to the positioning of the positioning point by the positioning portion until the PCBA board is located at the specified position.

As a preferred embodiment, the packaging method comprises controlling the glue spraying assembly to spray UV glue liquid with a viscosity of 5-25 cP to the PCBA plate, and further controlling the glue spraying assembly to spray UV glue liquid with a viscosity of 8-20 cP to the PCBA board.

As a preferred embodiment, the packaging method comprises curing the glue on the PCBA board while spraying the glue onto the PCBA board, wherein the position of the PCBA board is fixed during the glue curing process.

As a preferred embodiment, during the spraying process, the movement speed of the glue spraying assembly is controlled to be lower than 50 mm/s, and further, the movement speed of the glue spraying assembly is controlled to be lower than 30 mm/s, and further, the movement speed of the glue spraying assembly is controlled to be lower than 20 mm/s.

As a preferred embodiment, the packaging method further comprises:
obtaining a glue spraying information picture carrying spraying area information;
identifying the spraying area information of the glue spraying information picture and obtaining the target spraying area of the PCBA board.

As a preferred embodiment, the glue spraying information picture is a bitmap.

As a preferred embodiment, shape size of the bitmap is in a predetermined proportional relationship to shape size of the PCBA board.

As a preferred embodiment, the glue spraying information picture shows a spraying area by a predetermined color distinguished from base color, wherein a base color area is identified as a non-glue spraying area, a predetermined color area is identified as the target spraying area, and a distribution position of the predetermined color area relative to the base color area corresponds to a distribution position of the target spraying area on the PCBA board.

As a preferred embodiment, the glue spraying information picture is drawn according to the gerber diagram of the PCBA board.

As a preferred embodiment, the packaging method comprises:
controlling the glue spraying assembly to spray a first number of target spraying layers of UV glue liquid to the surrounding of a target electronic element by moving back and forth in a straight line in a horizontal direction, to form a fence surrounding the target electronic element;
controlling the glue spraying assembly to spray a second number of target spraying layers of UV glue liquid to an area surrounded by the fence by moving back and forth in a straight line in the horizontal direction, to fill and level up the fence.

As a preferred embodiment, the packaging method comprises:
obtaining a glue spraying information picture carrying spraying area information of the fence and a first number of target spraying layers;
according to the spraying area information of the fence, controlling the glue spraying assembly to spray the first number of target spraying layers of UV glue liquid to the surrounding of a target electronic element by reciprocating in a straight line, to form a fence surrounding the target electronic element;
obtaining a glue spraying information picture carrying the filled and leveled-up spraying area information and a second number of target spraying layers;
according to the filled and leveled-up spraying area information, controlling the glue spraying assembly to spray a second number of target spraying layers of UV glue liquid to the fence by moving back and forth in a straight line in the horizontal direction, to fill and level up the fence.

As a preferred embodiment, the glue spraying assembly is a piezoelectric array nozzle; in the packaging method, the glue spraying assembly is controlled to spray UV glue liquid with a viscosity of 5-25 cP at 40-50° C. to the PCBA board.

A PCBA board packaging device comprising:
a glue spraying assembly having a plurality of spraying holes through which spraying is controlled independently;
a first moving assembly connected to the glue spraying assembly; the first moving assembly is used to drive the glue spraying assembly to move back and forth in a straight line in a horizontal direction;
a working table located below the spraying holes, the working table having a placement surface for placing a PCBA board;
a control device connected to the glue spraying assembly and the first moving assembly, the control device capable of controlling the glue spraying assembly to spray UV glue liquid to a target spraying area of the PCBA board by moving back and forth in a straight line in a horizontal direction.

A packaging method for a PCBA board, comprising:
obtaining a glue spraying information picture carrying spraying area information;
identifying the spraying area information of the glue spraying information picture and obtaining the target spraying area of the PCBA board;
controlling the glue spraying assembly to spray UV glue liquid to a target spraying area of the PCBA board.

As a preferred embodiment, the PCBA board comprises a printed circuit board and an electronic element arranged on the printed circuit board; the maximum height of the electronic element relative to surface of the printed circuit board is less than 1 cm.

The packaging method comprises: controlling the glue spraying assembly to spray UV glue liquid with a viscosity of 5-25 cP at 40-50° C. to a target spraying area of the PCBA board by moving back and forth in a straight line in a horizontal direction.

As a preferred embodiment, the glue spraying information picture is a bitmap; the pixel points of the glue spraying information picture correspond to different position points of the PCBA board one by one.

As a preferred embodiment, shape size of the bitmap is in a predetermined proportional relationship to shape size of the PCBA board.

As a preferred embodiment, the glue spraying information picture shows a spraying area by a predetermined color distinguished from base color, wherein a base color area is identified as a non-glue spraying area, a predetermined color area is identified as the target spraying area, and a distribution position of the predetermined color area relative to the base color area corresponds to a distribution position of the target spraying area on the PCBA board.

As a preferred embodiment, the glue spraying information picture is drawn according to the gerber diagram of the PCBA board.

As a preferred embodiment, the packaging method comprises:
controlling the glue spraying assembly to spray a first number of target spraying layers of UV glue liquid to the surrounding of a target electronic element by moving back and forth in a straight line in a horizontal direction, to form a fence surrounding the target electronic element;
controlling the glue spraying assembly to spray a second number of target spraying layers of UV glue liquid to an area surrounded by the fence by moving back and forth in a straight line in the horizontal direction, to fill and level up the fence.

As a preferred embodiment, the packaging method comprises:
obtaining a glue spraying information picture carrying spraying area information of the fence and a first number of target spraying layers;
according to the spraying area information of the fence, controlling the glue spraying assembly to spray the first number of target spraying layers of UV glue liquid to the surrounding of a target electronic element by reciprocating in a straight line, to form a fence surrounding the target electronic element;
obtaining a glue spraying information picture carrying the filled and leveled-up spraying area information and a second number of target spraying layers;
according to the filled and leveled-up spraying area information, controlling the glue spraying assembly to spray a second number of target spraying layers of UV glue liquid to the fence by moving back and forth in a straight line in the horizontal direction, to fill and level up the fence.

As a preferred embodiment, the glue spraying information picture of the glue spraying assembly is controlled to be one during one time glue spraying process in which the glue spraying assembly starts moving and stops moving.

A PCBA board packaging device comprising:
a glue spraying assembly having a plurality of spraying holes through which spraying is controlled independently;
a first moving assembly connected to the glue spraying assembly; the first moving assembly is used to drive the glue spraying assembly to move back and forth in a straight line in a horizontal direction;
a working table located below the spraying holes, the working table having a placement surface for placing a PCBA board;
an obtaining module for obtaining spraying area information;
a control device connected to the glue spraying assembly, the first moving assembly and an obtaining module, the control device capable of controlling the glue spraying assembly to spray UV glue liquid to a target spraying area of the PCBA board by moving back and forth in a straight line in a horizontal direction.

A PCBA board packaging UV glue liquid suitable for a piezoelectric array nozzle is provided, wherein the viscosity of the UV glue liquid is 5-25 cP at 40-50° C., the surface tension is 20-40 mN/m, the density is 0.8-1.2 g/cm3, and the pH value is 6-8.

As a preferred embodiment, the viscosity of the UV glue liquid is 10-15 cP, the surface tension is 25-35 mN/m, and the density is 0.9-1.0 g/cm3.

As a preferred embodiment, the UV glue liquid is colorless transparent or light yellow transparent glue.

As a preferred embodiment, the UV glue liquid comprises an acrylic resin (oligomer) with a concentration range of 10%-30%, an acrylic monomer (reactive diluent) with a concentration range of 60%-80%, a photoinitiator with a concentration range of 2%-10%, and an additive with a concentration range of 0.05%-2%.

A PCBA board packaging UV glue liquid suitable for a piezoelectric array nozzle is provided, the UV glue liquid comprises an acrylic resin (oligomer) with a concentration range of 8%-35%, an acrylic monomer (reactive diluent) with a concentration range of 55%-85%, a photoinitiator with a concentration range of 1.5%-10.5%, and an additive with a concentration range of 0.02%-2.3%.

As a preferred embodiment, the UV glue liquid comprises an acrylic resin (oligomer) with a concentration range of 10%-30%, an acrylic monomer (reactive diluent) with a concentration range of 60%-80%, a photoinitiator with a concentration range of 2%-10%, and an additive with a concentration range of 0.05%-2%.

A piezoelectric array nozzle for packaging a PCBA board is provided, wherein the nozzle has a glue spraying panel on which a plurality of parallel spraying hole rows are distributed; each spraying hole row has a plurality of spraying holes through which spraying is controlled independently that are arranged in a first direction; the plurality of spraying hole rows are arranged in a second direction perpendicular to the first direction; in the spraying hole rows, a hole spacing portion is provided between two adjacent spraying holes; at least one hole spacing portion is at least partially aligned with at least one spraying hole in the other rows of spraying holes in the second direction.

As a preferred embodiment, a spraying hole in one spraying hole row is at least partially staggered from the nearest spraying hole in the other spraying hole row in the second direction.

As a preferred embodiment, in two adjacent spraying hole rows, each spraying hole is staggered in the second direction.

As a preferred embodiment, the glue spraying panel is provided with more than five rows of spraying holes; each spraying hole row contains at least 50 or more spraying holes.

As a preferred embodiment, each spraying hole row contains at least 100 or more spraying holes.

As a preferred embodiment, a single drop volume of the spraying hole ranges from 50 to 100 picoliters.

As a preferred embodiment, spraying hole rows at two sides of a spraying hole row are aligned one by one in the second direction; in each spraying hole row, the spacings between two adjacent spraying holes are equal.

As a preferred embodiment, two adjacent staggered spraying hole rows constitute a spraying hole group; a plurality of parallel spraying hole groups are arranged in the second direction on the glue spraying panel; in the second direction, a spacing distance between two adjacent spraying hole groups is greater than a spacing distance between two spraying hole rows in the spraying hole group.

As a preferred embodiment, the hole spacing portion is aligned with a spraying hole at the middle in the second direction.

A PCBA board packaging device comprising: a piezoelectric array nozzle according to any of the above embodiments.

A PCBA board packaging device comprising:
a glue spraying assembly having a plurality of spraying holes through which spraying is controlled independently;
a first moving assembly connected to the glue spraying assembly; the first moving assembly is used to drive the glue spraying assembly to move back and forth in a straight line in a horizontal direction;
a working table located below the spraying holes, the working table having a placement surface for placing a PCBA board.

As a preferred embodiment, the glue spraying assembly is fixedly provided with at least one array nozzle; wherein the array nozzle has a glue spraying panel on which a plurality of parallel spraying hole rows are distributed; each spraying hole row has a plurality of spraying holes through which spraying is controlled independently that are arranged in a first direction; the plurality of spraying hole rows are arranged in a second direction perpendicular to the first direction; in the spraying hole rows, a hole spacing portion is provided between two adjacent spraying holes; at least one hole spacing portion is at least partially aligned with at least one spraying hole in the other spraying hole row in the second direction.

As a preferred embodiment, the first direction is perpendicular to the first horizontal direction.

As a preferred embodiment, the glue spraying assembly is also fixedly provided with a curing light source; the curing light source is an LED lamp with a wavelength of 365-395 nm.

As a preferred embodiment, the curing light source is located on at least one side of the glue spraying assembly in the first horizontal direction; orientation of a light-emitting surface of the curing light source is perpendicular to the working table.

As a preferred embodiment, the curing light source is further provided with a water cooling heat dissipation structure. The light-emitting surface of the curing light source is arranged vertically downwards.

As a preferred embodiment, the horizontal spacing between the curing light source and the array nozzle is greater than 5 cm.

As a preferred embodiment, the glue spraying assembly is further provided with a positioning portion for positioning the PCBA board; further, the positioning portion includes a visual positioning assembly.

As a preferred embodiment, the first moving assembly comprises an electric cylinder and a linear guide rail; the glue spraying assembly comprises a glue spraying support which can be arranged slidably on the linear guide rail and driven by the electric cylinder to reciprocate in a straight line along the linear guide rail; the array nozzle is fixedly arranged on the glue spraying support.

As a preferred embodiment, the PCBA board packaging device further comprises:
a rotating assembly for driving the working table to rotate around a vertical axis;
a second moving assembly for driving the working table to move in a second horizontal direction perpendicular to the first horizontal direction; the working table is operatively and rotationally supported on the rotating assembly; the rotating assembly is arranged on the second moving assembly and is driven to move in the second horizontal direction.

The invention has the following beneficial effects:

The packaging method for a PCBA board provided in an embodiment of the present disclosure is capable of controlling the glue spraying assembly to spray UV glue liquid to the target spraying area of the PCBA board by moving back and forth in a horizontal direction, and is suitable for reliable packaging of a PCBA board with low height. In addition, the UV glue liquid curing efficiency is high, and thus local areas of the PCBA board can be quickly and reliably packaged, and the production efficiency is high.

The packaging method for a PCBA board provided in an embodiment of the present disclosure can obtain and identify the spraying area information according to the glue spraying information picture, so as to locally spray glue on the target spraying area of the PCBA board on the working table, and thus capable of accurately positioning and packaging part of the PCBA board.

An embodiment of the present disclosure provides a PCBA board packaging UV glue liquid suitable for a piezoelectric array nozzle, with which a glue flow path of the piezoelectric array nozzle is not blocked, such that the UV glue liquid can be quickly cured on the PCBA board to enclose the electronic element, so as to provide reliable protection against electronic elements on the PCBA board.

An embodiment of the present disclosure provides a piezoelectric array nozzle, which has multiple spraying points and can accurately control the spraying points (spraying holes) for spraying glue at pixel points, can spray UV glue at accurate position of the electronic elements on the PCBA board to achieve pixel-level packaging of the PCBA board.

With reference to the specification and drawings below, a specific embodiment of the present disclosure is disclosed in detail, which specifies the manner in which the principle of the present disclosure can be adopted. It should be understood that the embodiment of the present disclosure is not thus limited in scope.

The features described and/or shown for one embodiment can be used in one or more other embodiments in the same or similar manner, can be combined with the features in other embodiments or replace the features in other embodiments.

It should be emphasized that, the term “include/contain” refers to, when being used in the text, existence of features, parts, steps or assemblies, without exclusion of existence or attachment of one or more other features, parts, steps or assemblies.

### BRIEF DESCRIPTION OF THE DRAWINGS

In order to more clearly explain the embodiments of the present disclosure or the technical solution in the prior art, drawings that need to be used in the description in embodiments or the prior art will be simply introduced below, obviously the drawings in the following description are merely some examples of the present disclosure, for persons ordinarily skilled in the art, it is also possible to obtain other drawings according to these drawings without making creative efforts.

FIG. 1 is a schematic diagram of a packaging device provided by an embodiment of the present disclosure;

FIG. 2 is a schematic diagram of an internal glue spraying assembly and a working table structure in FIG. 1;

FIG. 3 is a partial schematic diagram of FIG. 2;

FIG. 4 is a front view of FIG. 3;

FIG. 5 is a structural schematic diagram of the glue spraying assembly in FIG. 2;

FIG. 6 is a schematic diagram of arrangement of spraying holes of a piezoelectric array nozzle provided by an embodiment of the present disclosure;

FIG. 7 is a schematic diagram of arrangement of spraying holes of a piezoelectric array nozzle provided by another embodiment of the present disclosure;

FIG. 8 is a schematic diagram of the glue spraying process in FIG. 1;

FIG. 9 is a schematic diagram of a fence-type package chip for the packaging method for a PCBA board provided by an embodiment of the present disclosure;

FIG. 10 is a schematic diagram of a separately printed fence for the packaging method for a PCBA board provided by an embodiment of the present disclosure;

FIG. 11 shows a glue spraying information picture for the packaging method for a PCBA board provided by an embodiment of the present disclosure;

FIG. 12 shows a fence glue spraying information picture for the packaging method for a PCBA board provided by another embodiment of the present disclosure;

FIG. 13 shows a filling glue spraying information picture for the packaging method for a PCBA board provided by another embodiment of the present disclosure;

FIG. 14 is a schematic diagram of the spacing between a curing light source and an array nozzle for a PCBA board packaging device provided by an embodiment of the present disclosure;

FIG. 15 shows a flow chart of a PCBA board packaging method provided by an embodiment of the present disclosure.

1. Device housing; 2. observation window; 3. device door; 4. device support; 5. mounting platform; 6. support frame; 7. support plate; 10. glue spraying assembly; 11. nozzle; 15. first moving assembly; 16. positioning portion; 20. curing light source; 21. water cooling input connector; 22. water cooling output connector; 23. power supply connector; 25. mounting plate; 30. working table; 35. second moving assembly; 36. rotating assembly; 12. glue liquid input connector; 13. glue liquid output connector;
113. spraying hole group; 114. spraying hole row; 115. glue spraying panel; 116. spraying hole; 117. spacing portion; F1. first direction; F2. second direction; 100. printed circuit board; 110. electronic element; 120. fence; 130. filled portion; 101. non-glue spraying area (base color area); 102. glue spraying area (predetermined color area).

### DETAILED DESCRIPTION OF THE PREFERRED EMBODIMENTS

In order to make those skilled in the art better understand the technical solutions in the present disclosure, the technical solutions in the embodiments of the present disclosure will be clearly and completely described in the following with reference to the accompanying drawings in the embodiments of the present disclosure. Obviously, the described embodiments are only a part of the embodiments of the present disclosure, but not all of them. Any other embodiment obtained by those skilled in the art based on the embodiments of the present disclosure without paying any creative labor shall fall within the protection scope of the present disclosure.

It should be noted that when an element is referred to as being “disposed” on another element, it may be directly on another element or there may be another element in the middle. When one element is considered to be “connected” to another element, it may be connected directly to another element or there may be another element in the middle. The terms “vertical,” “horizontal,” “left,” “right” and other similar expressions used herein are used for illustrative purposes only and are not meant to be the only embodiment.

Unless otherwise defined, all technical and scientific terms used herein have the same meanings as that are generally understood by those skilled in the art belonging to the technical field of the present disclosure. The terms used herein in the description of the present disclosure are for purposes of describing specific embodiments only and are not intended to limit the present disclosure. The terms “and/or” as used herein include any and all combinations of one or more related listed items.

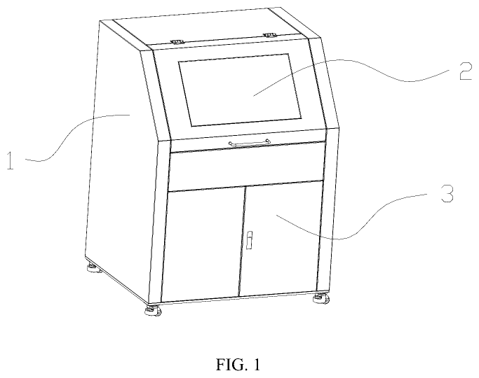

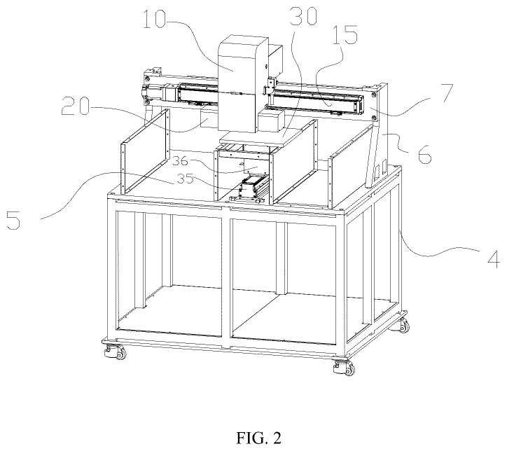

As shown in FIGS. 1 to 5, an embodiment of the present disclosure provides a PCBA board packaging device. The PCBA board packaging device is suitable for the protective packaging of an electronic element 110 on the PCBA board. The PCBA board comprises a printed circuit board 100 and the electronic element 110 arranged on the printed circuit board 100. In particular, the PCBA board packaging device is applicable to electronic packaging of a thin-type or patched PCBA board with low height. Specifically, the maximum height of the electronic element 110 relative to the surface of the printed circuit board 100 (PCB) is less than 1 cm. Further, the maximum height of the electronic element 110 relative to the surface of the printed circuit board 100 is less than 0.5 mm.

In this embodiment, the PCBA board packaging device comprises: a glue spraying assembly 10, a first moving assembly 15, and a working table 30. The working table 30 is arranged on device support 4. The device support 4 has a mounting platform 5 on which the working table 30 is mounted. The mounting platform 5 is provided with a support frame 6 supporting the first moving assembly 15. The support frame 6 supports the glue spraying assembly 10 and the first moving assembly 15 across the mounting platform 5, to form a similar gantry mechanism. A support plate 7 is supported on the support frame 6, and the first moving assembly 15 is fixedly mounted on a front plate surface of the support plate 7.

The packaging device has a device housing 1 within which the glue spraying assembly 10, the first moving assembly 15 and the working table 30 are located, to avoid environmental impurities entering the glue liquid to affect the packaging quality. An observation window 2 is provided above the device housing 1 to observe the packaging of the PCBA board. After the PCBA board is packaged, the device door 3 where the observation window 2 is located can be opened by a handle, the PCBA board can be moved out, and a new PCBA board is sent into the device door. A storage door is arranged under the device housing 1, and a storage space is formed on the inside of the storage door.

The glue spraying assembly 10 has a plurality of spraying holes through which spraying is controlled independently. The first moving assembly 15 is connected to the glue spraying assembly 10. The first moving assembly 15 is used to drive the glue spraying assembly 10 to move back and forth in a straight line in a horizontal direction. The working table 30 is located below the spraying holes. The working table 30 is lower in height than the spraying holes. The working table 30 has a placement surface for placing a PCBA board.

The glue spraying assembly 10 is fixedly provided with at least one array nozzle 11. The array nozzle 11 is provided with a glue liquid input connector 12, a glue liquid output connector 13 to communicate with a glue liquid storage box. Each array nozzle 11 communicates with a glue liquid storage box through a glue liquid input connector 12 and a glue liquid output connector 13. Each array nozzle 11 provides glue liquid independently.

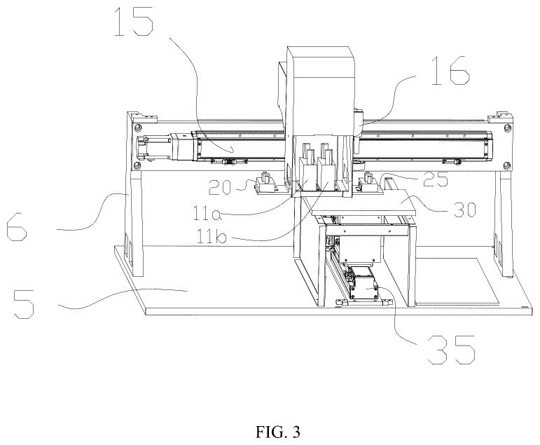

As shown in FIGS. 3, 4 and 5, the glue spraying assembly 10 comprises two array nozzles 11. The two array nozzles 11 are arranged in the first horizontal direction. The glue spraying assembly 10 remains unchanged at the height position of the packaging device. The array nozzle 11 is a piezoelectric array nozzle 11. The array nozzle 11 has a glue spraying panel 115 on which a plurality of parallel spraying hole rows 114 are distributed. That is, a plurality of parallel rows of spraying holes are distributed on the glue spraying panel 115. Each spraying hole row 114 has a plurality of spraying holes through which spraying is controlled independently that are arranged in a first direction F1. The plurality of spraying hole rows 114 are arranged in a second direction F2 perpendicular to the first direction F1.

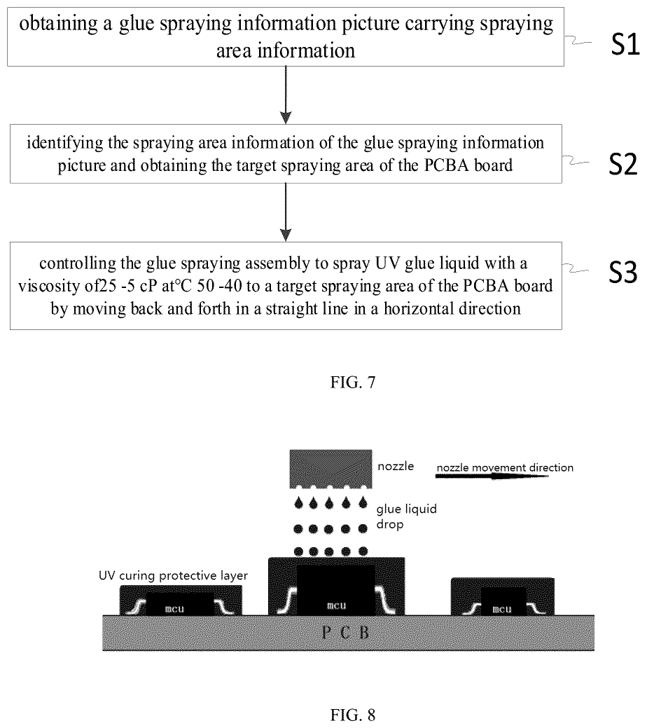

As shown in FIGS. 6 and 7, in the spraying hole row 114, there is a hole spacing portion 117 between two adjacent spraying holes. At least one hole spacing portion 117 is at least partially aligned with at least one spraying hole in the other spraying hole row 114 in the second direction F2. Further, the hole spacing portion 117 is aligned with a spraying hole at the middle in the second direction F2. The plurality of spraying hole rows 114 on the glue spraying panel 115 form a complete straight line along the projection of the second direction F2, so that when spraying glue, the plurality of spraying hole rows 114 can complement each other's points without spraying glue to form line spraying glue.

Thus, in two adjacent spraying hole rows 114, the spraying hole in one spraying hole row 114 is aligned with the hole spacing portion 117 in the other spraying hole row 114 along the second direction F2, and the spraying holes are staggered from each other. In this way, the hole spacing portion 117 of the spraying hole row 114 is compensated by the spraying holes in the adjacent spraying hole row 114 on the second direction F2 (traveling direction of the nozzle 11, i.e., the first horizontal direction described below), which can not only reduce the size of the spraying hole, increase the number of the spraying holes, improve the accuracy of the glue spraying position, but also avoid occurrence of the unsprayed glue points, spray glue more evenly, and improve the packaging quality. The first direction F1 is perpendicular to the first horizontal direction. The second direction F2 is parallel to the first horizontal direction.

The glue spraying assembly is also fixedly provided with a curing light source 20. The curing light source 20 is an LED lamp with a wavelength of 365-395 nm. UV energy is 8000 mW/cm3. The curing depth of the curing light source 20 is 100-3000 μm. The curing light source 20 is located on at least one side of the glue spraying assembly 10 in the first horizontal direction. Orientation of a light-emitting surface of the curing light source 20 is perpendicular to the working table 30. The curing light source 20 is further provided with a water cooling heat dissipation structure. The light-emitting surface of the curing light source 20 is arranged vertically downwards. The curing light source 20 is provided with a water cooling input connector 21 and a water cooling output connector 22. A power supply connector 23 (a cable connector) is provided between the water cooling input connector 21 and the water cooling output connector 22 to input electrical energy.

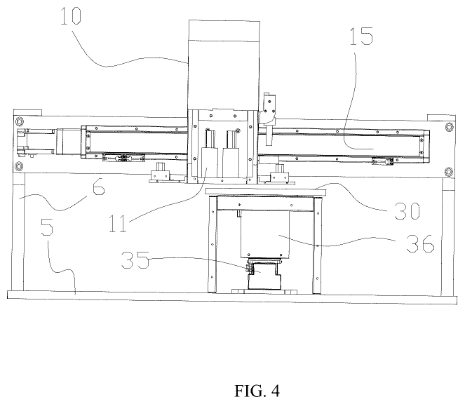

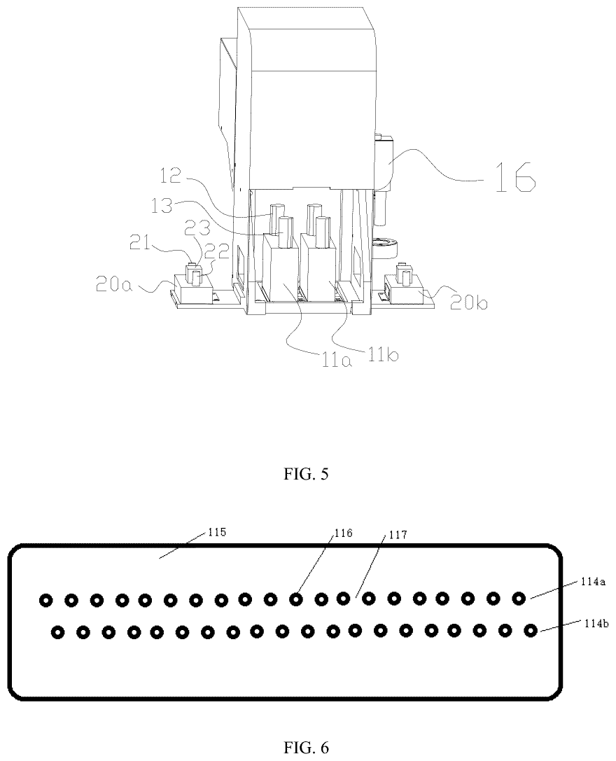

As shown in FIGS. 4 and 5, both sides of the glue spraying assembly 10 in the first horizontal direction are respectively provided with curing light sources 20. The glue spraying assembly 10 is provided with a horizontal mounting plate 25 at a lower end thereof. The two curing light sources 20 (UV lamps) are respectively mounted on the mounting plate 25 and are at the same level (at the same height) as the array nozzle 11. When moving in the first horizontal direction, the curing light sources 20 of the glue spraying assembly 10 at a rear side in the moving direction can be opened to realize the curing followed after spraying, so that the spraying and curing can be carried out at the same time.

As shown in FIG. 14, in order to have a better curing effect and avoid the curing light source 20 from affecting the spraying of glue liquid (mainly to avoid liquid drop from being cured before coming into contact with PCBA), the horizontal spacing L5 between the curing light source 20 and the array nozzle 11 is greater than 5 cm. The horizontal spacing L5 between the curing light source 20 and the array nozzle 11 is within 15 cm.

The glue spraying assembly 10 is further provided with a positioning portion 16 for positioning the PCBA board. As shown in FIG. 4, the positioning portion 16 is fixed on a side of the glue spraying assembly 10 in the first horizontal direction. When facing FIG. 4, the positioning portion 16 is fixed on the right side of the glue spraying assembly 10, and is adjacent to the right curing light source 20. The curing light source 20 does not interfere with the positioning portion 16. Specifically, the positioning portion 16 comprises a visual positioning assembly. For example, the positioning portion 16 includes a CCD visual positioning system. The PCBA board has a specific position point or a predetermined electronic element 110 that can be identified by a visual positioning assembly. The specific position point or the predetermined electronic element 110 can be positioned by the positioning portion 16, the working table 30 is adjusted according to the positioning situation, and the PCBA board is precisely adjusted to the specified glue spraying position. In other embodiments, the positioning portion 16 may also be an ultrasonic positioning device.

In this embodiment, the first moving assembly 15 comprises a lead screw module. The lead screw module has a servo motor and a lead screw driven by the servo motor to rotate. The lead screw module is provided with a sliding block sliding along the lead screw. The glue spraying assembly 10 comprises a glue spraying support fixedly connected with the sliding block, and the glue spraying assembly 10 performs linear reciprocating movement along with the sliding block. The glue spraying assembly 10 constitutes a glue spraying support of the glue spraying housing, within which a plurality of array nozzles 11 are fixed, or the array nozzles 11 are arranged in a fixed configuration as a bottom of the glue spraying support facing downwards, i.e., the glue spraying panel 115 of the array nozzles 11.

In other embodiments, the first moving assembly 15 comprises an electric cylinder and a linear guide rail. The glue spraying assembly 10 comprises a glue spraying support which can be arranged slidably on the linear guide rail and driven by the electric cylinder to reciprocate in a straight line along the linear guide rail; the array nozzle 11 is fixedly arranged on the glue spraying support.

The movement speed of the nozzle 11 is too fast, causing the error after curing to be greater, however, if the speed of the nozzle 11 is too low, the curing effect and packaging efficiency of glue liquid do not meet the expectations. In order to avoid these problems, during the glue spraying process, the movement speed of the glue spraying assembly 10 is controlled to be lower than 50 mm/s, further, the movement speed of the glue spraying assembly 10 is controlled to be lower than 30 mm/s, and further, the movement speed of the glue spraying assembly 10 is controlled to be lower than 20 mm/s.

In this embodiment, the packaging device further comprises a rotating assembly 36 and a second moving assembly 35. The rotating assembly 36 is used for driving the working table 30 to rotate around a vertical axis. The second moving assembly 35 is used for driving the working table 30 to move in a second horizontal direction perpendicular to the first horizontal direction. The working table 30 is operatively and rotationally supported on the rotating assembly 36. The rotating assembly 36 may be a rotating servo motor, and the working table 30 is connected to an output end of the rotating servo motor, or the working table 30 is connected to the output end of the rotating servo motor through a deceleration mechanism such as a decelerator. The second moving assembly 35 can refer to the first moving assembly 15. The rotating assembly 36 is arranged on the second moving assembly 35 and is driven to move in the second horizontal direction. The rotating assembly 36, together with the working table 30, is moved by the second moving assembly 35 along the second horizontal direction and can be positioned at a predetermined position.

The PCBA board placed on the working table 30 is precisely positioned by rotating in the plane and adjusting the height of the working table 30, and the PCBA board is adjusted to the prescribed spraying position, which is convenient to achieve accurate spraying packaging in the subsequent spraying process. The position of the glue spraying assembly 10 is fixed in the second horizontal direction and can only move in a straight line in the first horizontal direction. When the PCBA board width is too large, the nozzle 11 is moved by the working table 30 in the second horizontal direction when the spraying cannot completed at one time, such that the glue spraying assembly 10 successively sprays glue on different areas of the PCBA board to thereby achieve spraying protection of a large-area PCBA board.

In order to realize the automation of packaging and improve production efficiency, in an embodiment, the packaging device further comprises a control device connected to the glue spraying assembly 10 and the first moving assembly 15, and the control device is capable of controlling the glue spraying assembly 10 to spray UV glue liquid to a target spraying area of the PCBA board by moving back and forth in a straight line in a horizontal direction.

In another embodiment, the packaging device further comprises an obtaining module for obtaining spraying area information and a control device connected to the glue spraying assembly 10, the first moving assembly 15 and an obtaining module. The control device is capable of controlling the glue spraying assembly 10 to spray UV glue liquid to a target spraying area of the PCBA board by moving back and forth in a straight line in a horizontal direction.

The obtaining module includes a network transmission module, or drawing software, or mapping software, or a data transmission interface such as a USB interface, a type-C interface or the like, to input or import a glue spraying information picture. The obtaining module can also include an information input device such as a touch screen or a keyboard or the like to input a number of target spraying layers. An upper computer software runs on the controller.

An embodiment of the present disclosure provides a piezoelectric array nozzle 11 for packaging a PCBA board, wherein the nozzle 11 has a glue spraying panel 115 on which a plurality of parallel spraying hole rows 114 are distributed. Each spraying hole row 114 has a plurality of spraying holes through which spraying is controlled independently that are arranged in a first direction F1. The plurality of spraying hole rows 114 are arranged in a second direction F2 perpendicular to the first direction F1. In the spraying hole row 114, there is a hole spacing portion 117 between two adjacent spraying holes. At least one hole spacing portion 117 is at least partially aligned with at least one spraying hole in the other spraying hole row 114 in the second direction F2.

A spraying hole in one spraying hole row 114 is at least partially staggered from the nearest spraying hole in the other spraying hole row in the second direction F2. In two adjacent spraying hole rows 114, each spraying hole is staggered in the second direction F2. Spraying hole rows 114 at two sides of a spraying hole row 114 are aligned one by one in the second direction F2. The glue spraying panel 115 is provided with more than five rows of spraying holes. Each spraying hole row 114 contains at least 50 or more spraying holes. Further, each spraying hole row 114 contains at least 100 or more spraying holes. The spacing between two spraying holes is smaller than the diameter of the spraying hole. Of course, in some embodiments, the spacing between the spraying holes is greater than the diameter of the spraying hole.

A single drop volume of the spraying hole ranges from 50 to 100 picoliters. Or one-time spraying glue of the spraying hole ranges from 50 to 100 picoliters. The glue liquid is output continuously through spraying glue by the spraying hole at a high frequency. Each spraying hole of the nozzle 11 can spray up to 20,000 times per second.

As shown in FIG. 7, two adjacent staggered spraying hole rows 114 constitute a spraying hole group 113. A plurality of parallel spraying hole groups 113 are arranged in the second direction F2 on the glue spraying panel 115. The plurality of spraying hole groups 113 are symmetrically arranged on the glue spraying panel 115. Or plurality of spraying hole groups 113 are of a translational structure. In the second direction F2, a spacing distance between two adjacent spraying hole groups 113 is greater than a spacing distance between two spraying hole rows 114 in the spraying hole group 113. The hole spacing portion 117 is aligned with a spraying hole at the middle in the second direction F2.

An embodiment of the present disclosure provides a packaging method for a PCBA board. The packaging method is applicable to, but not limited to, a PCBA board with low height (which can also be directly referred to as PCBA). The PCBA board comprises a printed circuit board 100 and the electronic element 110 arranged on the printed circuit board 100. The maximum height of the electronic element 110 relative to the surface of the printed circuit board 100 (PCB) is less than 1 cm. Further, the maximum height of the electronic element 110 relative to the surface of the printed circuit board 100 is less than 0.5 mm, which is also applicable to the packaging method and device of the present disclosure. The packaging method may be implemented using the packaging device in the above embodiment.

As shown in FIG. 8, the packaging method comprises: controlling the glue spraying assembly 10 to spray UV glue liquid to a target spraying area of the PCBA board by moving back and forth in a straight line in a horizontal direction. The glue spraying assembly 10 is not changed in height position during movement. The glue spraying assembly 10 moves back and forth in a straight line at a height position. In the process of spraying glue, the glue spraying assembly 10 sprays UV glue liquid to a target spraying area of the PCBA board by moving back and forth in a straight line in a horizontal direction.

In the packaging method, the glue spraying assembly 10 is positioned above the highest electronic element 110 and the spacing between the glue spraying assembly 10 and the highest electronic element 110 is controlled to be less than 2 mm. Further, the spacing between the glue spraying assembly 10 and the highest electronic element 110 is controlled to be less than 1 mm.

In order to avoid interference between the electronic element 110 on the PCBA board and the moving path of the glue spraying assembly 10, the glue (glue drops) will be dispersed, and the spacing between the glue spraying assembly 10 and the PCBA board will not be too large. The glue spraying assembly 10 adopts an array nozzle 11 such as a piezoelectric array nozzle 11. The spraying hole is small, and the initial speed of the glue droplets emitted is fast, but the speed damage is also fast, which may easily cause the problem of drifting. In order to avoid this problem, the spacing between the glue spraying assembly 10 and the highest electronic element 110 is controlled to be less than 2 mm or even within 1 mm.

Relative height of the glue spraying assembly and the PCBA board is unchanged during the glue spraying process. During the glue spraying process, the glue spraying assembly 10 is controlled to move back and forth in a horizontal straight line to spray UV glue liquid to the target spraying area of the PCBA board until the spraying package is completed. The PCBA board is placed horizontally on the working table 30. The glue spraying assembly 10 is controlled to spray glue on the PCBA board on the working table 30 in such a way that a spraying hole is vertically oriented toward the working table 30.

As shown in FIG. 8, one spraying layer is formed by one linear one-way movement of the glue spraying assembly 10 (such as the nozzle 11 in FIG. 8), and two spraying layers are formed by one linear round-trip movement. The one linear round-trip movement of the glue spraying assembly 10 includes two one-way movements. The packaging method further comprises: obtaining number of target spraying layers; controlling the glue spraying assembly 10 to spray UV glue liquid to a target spraying area of the PCBA board by moving back and forth in a straight line in a horizontal direction until the target spraying area reaches the number of target spraying layers.

The packaging method comprises placing the PCBA board horizontally on the working table 30. The PCBA board has a positioning point; the glue spraying assembly 10 is provided with a positioning portion 16 for positioning the positioning point. The packaging method comprises: moving the glue spraying assembly 10 and controlling the working table 30 to move according to the positioning of the positioning point by the positioning portion 16 until the PCBA board is located at the specified position. The controller of the packaging device can be provided beforehand with a two-dimensional position with positioning points.

In the packaging method, the glue spraying assembly 10 is controlled to spray UV glue liquid with a viscosity of 5-25 cP into the PCBA plate. Further, the glue spraying assembly 10 is controlled to spray UV glue liquid with a viscosity of 8-20 cP into the PCBA plate. In the packaging method, the glue on the PCBA board is cured while the glue is sprayed onto the PCBA board. Of course, in other embodiments, in one round-trip movement, spraying is performed in one-way movement and curing is performed in one-way movement. At this time, curing is performed after the spraying.

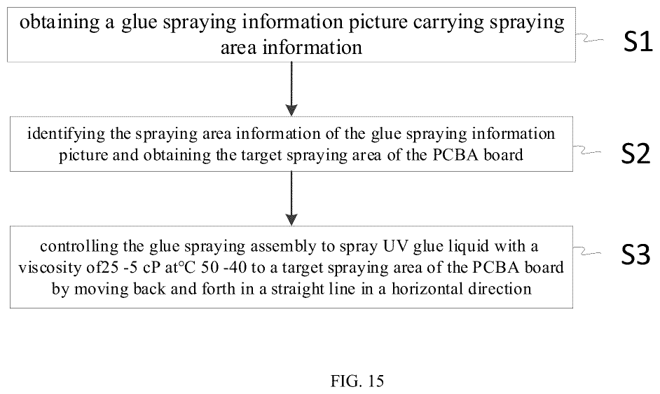

In an embodiment, as shown in FIG. 15, the packaging method comprises: a step S1 of obtaining a glue spraying information picture carrying spraying area information; a step S2 of identifying the spraying area information of the glue spraying information picture and obtaining the target spraying area of the PCBA board; a step S3 of controlling the glue spraying assembly 10 to spray UV glue liquid to the target spraying area of the PCBA board. Further, in the packaging method, the glue spraying assembly 10 is controlled to spray UV glue liquid with a viscosity of 5-25 cP at 40-50° C. to a target spraying area of the PCBA board by moving back and forth in a straight line in a horizontal direction.

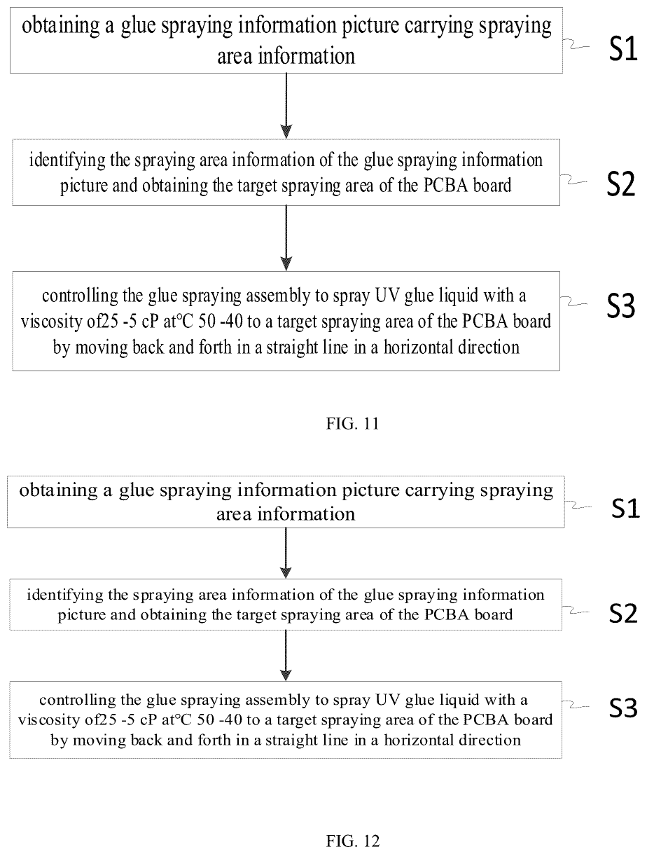

The packaging device has a controller that identifies a glue spraying information picture. The glue spraying information picture are shown in FIGS. 11, 12 and 13. It should be noted that the dotted line in FIGS. 11 to 13 is to mark the boundary of the picture to distinguish it from the color of the page, and there is no such dotted line in the actual picture. The controller of the packaging device has an identification module for identifying the spraying area information of the glue spraying information picture, and the identification module can be an identification software module running on the upper computer software.

The glue spraying information picture is a two-dimensional picture. The glue spraying information picture carries two-dimensional spraying information corresponding to a target spraying area of the PCBA board. The glue spraying information picture and the two-dimensional plane structure of the PCBA board are in a certain proportional relationship, and correspondingly, the location and shape of the spraying area information on the glue spraying information picture are also in a certain proportional relationship with the actual target spraying area. After identification

The glue spraying information picture is a bitmap. The pixel points of the glue spraying information picture correspond to different position points of the PCBA board one by one. A base color area 101 is identified as a non-glue spraying area, a predetermined color area 102 is identified as the target spraying area, and a distribution position of the predetermined color area 102 relative to the base color area 101 corresponds to a distribution position of the target spraying area on the PCBA board. Shape size of the bitmap is in a predetermined proportional relationship to shape size of the PCBA board. The glue spraying information picture is in the spraying area through a predetermined color. The glue spraying information picture is drawn according to the gerber diagram of the PCBA board.

As shown in FIGS. 11, 12 and 13, the base color is white or transparent, and the base color area 101 indicates that the area does not need to be sprayed for packaging. The black area 102 shows the shape and position of the spraying area, and the positions of the pixel points in the black area 102 correspond to the actual spraying areas one by one. Then, by identifying the position of the black pixel points, the corresponding position of the PCBA board can be sprayed to achieve accurate packaging.

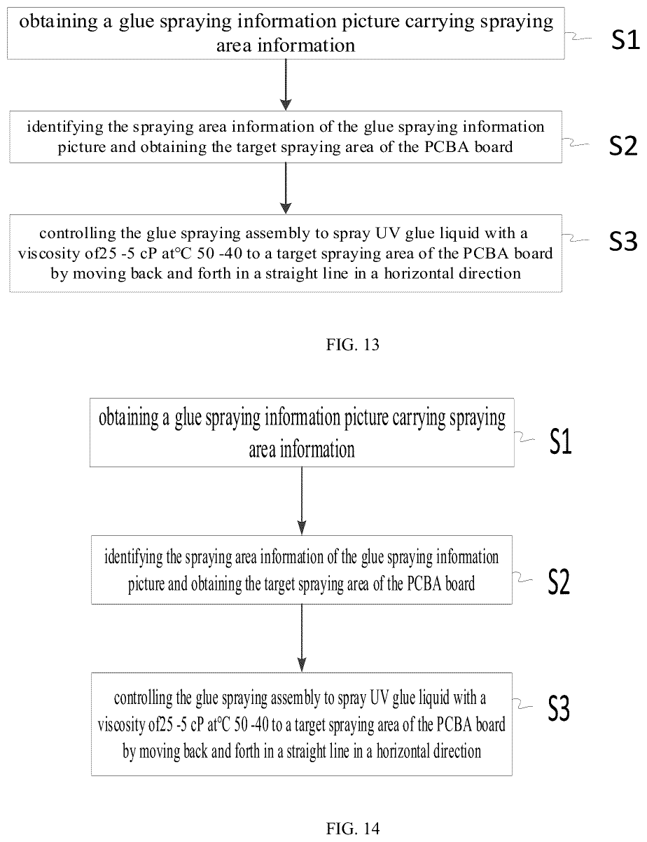

In an embodiment, the packaging method may be performed as direct spraying, which performs spraying at the same thickness around and above the electronic element 110 such as a patch element. For upper surface of some chips that need to be avoided, the sprayed pattern is edited so that the areas that do not need to be sprayed are not sprayed with color and are still marked with a base color such as white. The packaging method is generally suitable for thin layer protection, and the height of the electronic element 110 is lower than 0.5 mm. In this embodiment, the glue spraying information picture shown in FIG. 11 is imported, and the black spraying area 102 of the glue spraying information picture in FIG. 11 can be regarded as the black spraying area of FIG. 12 superimposed on the black spraying area of FIG. 13. Each pixel point of the black spraying area in FIG. 11 covers not only the surrounding of the electronic element 110 but also the top of the electronic element 110.

Combined with FIGS. 8, 9 and 10, in another embodiment, spraying encapsulation of the target electronic element 110 in the packaging method is performed as: a step S100 of controlling the glue spraying assembly 10 to spray a first number of target spraying layers of UV glue liquid to the surrounding of a target electronic element 110 by moving back and forth in a straight line in a horizontal direction, to form a fence 120 surrounding the target electronic element 110; a step S200 of controlling the glue spraying assembly 10 to spray a second number of target spraying layers of UV glue liquid to an area surrounded by the fence 120 by moving back and forth in a straight line in the horizontal direction, to fill and level up the fence 120.

In order to improve curing efficiency, the filled glue can be cured in one time after the fence 120 is filled. Of course, spraying and curing can also be performed at the same time when filling the fence 120, and filling is performed layer by layer while performing glue spraying and curing. In the process of printing the fence 120, spraying and curing are performed simultaneously.

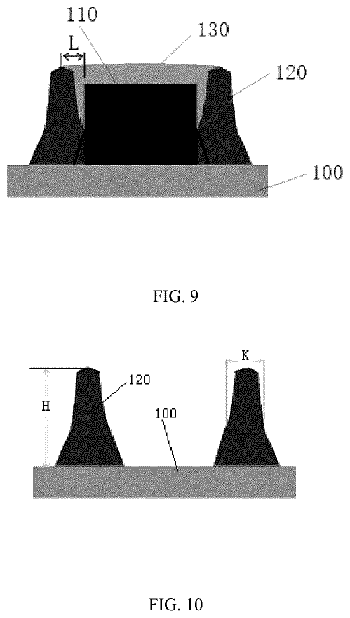

As shown in FIGS. 9 and 10, in order to have a better filling effect of the fence 120, the minimum value of wall thickness K of fence 120 is 0.5 mm, the maximum value of height H of fence 120 is 3 mm, and the minimum value of a gap L between the fence 120 and the electronic element 110 is 1 mm. After such packaging, the edge of the protective layer is straight and neat, the device is fully wrapped, and there is no sharp protrusion on the top.

Specifically, spraying encapsulation of the target electronic element 110 in the packaging method is performed as: a step S100 of obtaining a glue spraying information picture carrying spraying area information of the fence 120 and a first number of target spraying layers; a step S200 of, according to the spraying area information of the fence 120, controlling the glue spraying assembly 10 to spray a first number of target spraying layers of UV glue liquid to the surrounding of a target electronic element 110 by moving back and forth in a straight line, to form a fence 120 surrounding the target electronic element 110; a step S101 of obtaining a glue spraying information picture carrying the filled and leveled-up spraying area information and a second number of target spraying layers; a step 201 of, according to the filled and leveled-up spraying area information, controlling the glue spraying assembly 10 to spray a second number of target spraying layers of UV glue liquid to the fence 120 by moving back and forth in a straight line in the horizontal direction, to fill and level up the fence 120. The glue spraying information picture for the fence 120 as shown in FIG. 12 is imported in the step S100; and the glue spraying information picture for filling and leveling up as shown in FIG. 13 is imported in the step S101. After the step S201 is executed and curing is performed, the packaging effect as shown in FIG. 9 is formed, and the fence 120 is filled with a filled portion 130.

The glue spraying information picture of the glue spraying assembly 10 is correspondingly controlled to be one during one time glue spraying process in which the glue spraying assembly 10 starts moving and stops moving. Then the corresponding glue spraying information picture is re-imported or loaded when spraying glue in different areas or different PCBA boards next time. Each glue spraying information picture can correspond to one or more PCBA boards. FIG. 11 corresponds to the spraying area information of a PCBA board, and only one PCBA board can be sprayed for encapsulation when it is imported into FIG. 11. FIG. 12 and FIG. 13 respectively correspond to two PCBA boards 100a and 100b, and then two PCBA boards 100a and 100b can be packaged at the same time when they are imported into FIG. 12 or FIG. 13.

This embodiment is done by means of the fence 120 combined with filling. Firstly, multiple layers are sprayed around the chip to form the fence 120, when the height of the fence 120 is equal to the height of the chip, then the glue is filled inside the fence 120, and after the glue is leveled, the glue is cured in one time, so as to provide better protection for the chip with a higher height.

For the printing package of the PCBA board such as a test board, when a packaging method by the fence 120 combined with filling is adopted, FIG. 12 is imported into the upper computer software firstly, and it is set to print 40 layers, the glue spraying assembly 10 is started, then the glue spraying assembly 10 moves back and forth in a straight line to spray 40 layers around the target patch element to form the fence 120. Then FIG. 13 is imported, and set to be printed by 30layers, then filled by another 30 layers, and finally cured on the target patch element to form wrapped protection as shown in FIG. 9.

Another embodiment of the present disclosure provides PCBA board packaging UV glue liquid suitable for a piezoelectric array nozzle 11. The viscosity of the UV glue liquid is 5-25 cP at 40-50° C., the surface tension is 20-40 mN/m, the density is 0.8-1.2 g/cm3, and the pH value is 6-8 (test paper test). Further, the viscosity of the UV glue liquid is 10-15 cP, the surface tension is 25-35 mN/m, and the density is 0.9-1.0 g/cm3. The UV glue liquid is colorless transparent or light yellow transparent glue (under visual conditions).

The UV glue liquid comprises an acrylic resin (oligomer) with a concentration range of 10%-30%, an acrylic monomer (reactive diluent) with a concentration range of 60%-80%, a photoinitiator with a concentration range of 2%-10%, and an additive with a concentration range of 0.05%-2%. The UV glue liquid is of 100% solid content, has no solvent volatilization in the curing process, and has the characteristics of safety, health and environmental protection, non-toxic and harmless, non-flammable and explosive.

The UV glue liquid is a single-component, ultra-low viscosity, solvent-free glue for UV-curable electronic packaging. The UV glue liquid can be cured within 10 s under the irradiation of a certain wavelength of ultraviolet light (365-395 nm). The cured UV glue liquid has excellent performances such as water resistance, moisture resistance, cold and thermal shock resistance and mold resistance, and is suitable for the protection of various surface mounted PCBA welding spots, pins or discrete components.

The UV glue liquid has ultra-low viscosity characteristics and is suitable for selective spraying cover on the PCBA board by using the piezoelectric array nozzle 11 for ink-jet printing. The cured UV glue liquid can fluoresce under ultraviolet light, which is convenient to check the packaging effect.

In this embodiment, photoinitiator mainly includes free radical photoinitiator and cationic photoinitiator. In the UV glue liquid, auxiliary agents (additives) are added to meet the requirements of use, and the auxiliary agents can be pigments, wetting dispersants, polymerization inhibitors, etc. The effect of various auxiliary agents is significant, which can not only significantly improve the performance of UV, but also expand the application range and reduce the cost.

Preferably, the auxiliary agents can be inorganic nanomaterials, which can improve the performance of the cured protective layer and have enhanced toughness. Nanosized SiO2 is added into the UV glue liquid, which greatly improves the bonding performance and sealing effect. Specifically, when CYA-150 nanosilicon dioxide is selected as an auxiliary agent, the bonding strength of the adhesive can be significantly improved when the mass fraction is 2%.

The UV glue liquid provided in this embodiment forms a UV curable protective layer after being cured, and the UV curable protective layer has better mechanical and thermal properties. Specifically, the breaking strength of the UV curable protective layer is 5.4 Mpa at 25° C., and the elongation at break is 140%. The elastic modulus of the UV curing protective layer is 25.2 Mpa. The glass transition temperature of the UV curable protective layer is −15° C. The linear thermal expansion coefficient is 21.8 ppm/° C. in the range of −15° C. to 0° C. and 240.9 ppm/° C. in the range of 45° C. to 80° C.

In addition, the UV curable protective layer also has excellent electrical properties, the dielectric constant of the UV curable protective layer is 5.47 (1 GHz), and the breakdown strength is 15.8 kV/mm under the test condition of 1.5 mm thickness. The volume resistivity of the UV curable protective layer is 3.1×1014 Ω·cm without soaking water, and 1.7×1014 Ω·cm when soaking water at 23° C. for 168 hours. The UV curable protective layer has a surface resistance of 4.21×1010 Ω at 250V.

The UV curable protective layer also has excellent environmental reliability. After testing for 1000 hours at 85° C./85&RH, the surface of the UV curing protective layer has no significant changes, no bubbles, no rust, no cracks and no peeling, and it can be seen that the UV curing protective layer has better high temperature and high humidity resistance. The cold and thermal shock resistance test is carried out at −40° C./30 min to 1 min to 80° C./30 min (among which, the switching temperature time of 1 minute, that is, the heat preservation at −40 degrees for 30 minutes, and then switched to 80 degrees within 1 minute, and the heat preservation at 80 degrees for 30 minutes, and then cycle in turn). After cycling for 250 hours, the surface of the UV curing protective layer had no obvious change, no cracks and no peeling. In the salt spray resistance test, the UV curable protective layer has no significant change after 300 hours of testing under neutral smoke, and also has grade 0 mold resistance under mold resistance test.

In summary, it can be seen from the test results that the UV glue liquid combined with the piezoelectric array nozzle 11 can be accurately controlled within the package thickness in the range of 100-3000 μm, and the cured protective layer has excellent toughness, good resistance to mechanical shock, cold and thermal shock, high temperature and high humidity, and has high surface resistance and volume resistance, and can provide good insulation protection to the PCBA even in wet conditions.

The UV glue liquid adopts pure UV curing, and compared with UV curing with moisture, the curing and drying time of the UV glue liquid is greatly shortened, and due to the ultra-low viscosity and surface tension of the UV glue liquid, the UV glue liquid can be evenly spread without bubbles, and surface of the cured protective layer is smooth and the edge thereof is straight and neat.

Any numerical value referred to herein includes all values of a lower value and an upper value that are incremented by one unit from a lower limit value to an upper limit value, with an interval of at least two units between any lower value and any higher value. For example, if it is stated that the number of components or process variables such as temperature, pressure, time, etc., have a value from 1 to 90, preferably from 20 to 80, more preferably from 30 to 70, the purpose is to illustrate that the equivalents such as 15 to 85, 22 to 68, 43 to 51, 30 to 32 are also explicitly recited in the specification. For values smaller than 1, one unit is suitably considered to be 0.0001, 0.001, 0.01, 0.1. These are merely intended to be explicitly expressed examples, and it may be considered that all possible combinations of numerical values enumerated between the lowest value and the highest value are explicitly set forth in a similar manner in this specification.

Unless otherwise stated, all ranges include end points and all numbers between the end points. The “about” or “approximate” used with the range is suitable for both end points of the range. Thus, “about 20 to 30” is intended to cover “about 20 to about 30,” including at least the indicated end points.

All articles and references disclosed, including patent applications and publications, are incorporated herein by reference for all purposes. The term “consisting essentially of” to describe a combination should include the elements, components, parts or steps determined and other elements, components, parts or steps that do not substantially affect the substantially novel features of the combination. The use of the terms “comprising” or “including” to describe combination of the elements, components, parts or steps herein also contemplates embodiments that consist essentially of such elements, components, parts or steps. The use of the term “may” herein is intended to illustrate that any of the described attributes that may be included are optional.

The plurality of elements, components, parts or steps can be provided by a single integrated element, component, part or step. Alternatively, the single integrated element, component, part or step may be divided into separate multiple elements, components, parts or steps. A disclosed “a” or “an” used to describe an element, a component, a part or a step does not mean to exclude other elements, components, parts or steps.

It should be understood that the above description is for purposes of illustration and not for purposes of limitation. Many embodiments and many applications other than the examples provided will be apparent to those skilled in the art from reading the above description. Accordingly, the scope of the present teachings should not be determined with reference to the above description, but should be determined with reference to the appended claims and the full scope of equivalents owned by these claims. The disclosure of all articles and references, including patent applications and publications, is incorporated herein by reference for purposes of completeness. The omission of any aspect of the subject matter disclosed herein in the foregoing claims is not intended to waive the subject matter and the inventor should not be deemed to have considered the subject matter as a part of the disclosed subject matter.

What is claimed is:

1-20. (canceled)

21. A PCBA board packaging device, wherein the PCBA board packaging device comprises: a glue spraying assembly for spraying PCBA board packaging UV glue liquid; the glue spraying assembly has a glue spraying panel on which a plurality of parallel spraying hole rows are distributed; each spraying hole row has a plurality of spraying holes through which spraying is controlled independently that are arranged in a first direction;
the PCBA board packaging device further comprises:
a first moving assembly connected to the glue spraying assembly; the first moving assembly is used to drive the glue spraying assembly to move back and forth in a straight line in a horizontal direction;
a working table located below the glue spraying assembly, the working table having a placement surface for placing a PCBA board;
a control device connected to the glue spraying assembly and the first moving assembly, the control device capable of controlling the glue spraying assembly to spray UV glue liquid to a target spraying area of the PCBA board by moving back and forth in a straight line in a horizontal direction; the glue spraying assembly moves back and forth in a straight line at a height position higher than the highest electronic element; in the glue spraying process, the glue spraying assembly is not changed in height position during movement.

22. The PCBA board packaging device according to claim 21, wherein the control device has an identification module for identifying spraying area information of a glue spraying information picture; the glue spraying information picture is a two-dimensional bitmap.

23. The PCBA board packaging device according to claim 21, wherein the glue spraying assembly is a piezoelectric array nozzle.

24. The PCBA board packaging device according to claim 21, further comprising: a rotating assembly for driving the working table to rotate around a vertical axis; the working table is operatively and rotationally supported on the rotating assembly.

25. The PCBA board packaging device according to claim 24, further comprising: a second moving assembly on which the rotating assembly is arranged and is driven to move in a second horizontal direction; the first horizontal direction is perpendicular to the second horizontal direction; the rotating assembly, together with the working table, is moved by the second moving assembly along the second horizontal direction and can be positioned at a predetermined position.

26. The PCBA board packaging device according to claim 21, wherein the glue spraying assembly is further fixedly provided with a curing light source; the curing light source is an LED lamp with a wavelength of 365-395 nm; the curing light source is located on at least one side of the glue spraying assembly in the first horizontal direction; orientation of a light-emitting surface of the curing light source is perpendicular to the working table.

27. The PCBA board packaging device according to claim 21, wherein both sides of the glue spraying assembly in the first horizontal direction are respectively provided with curing light sources.

28. The PCBA board packaging device according to claim 21, wherein the PCBA board has a positioning point; the glue spraying assembly is provided with a positioning portion for positioning the positioning point;
the working table moves according to positioning of the positioning point by the positioning portion, and adjusts the PCBA board to a prescribed spraying position.

29. A PCBA board packaging method, wherein the PCBA board packaging method is implemented by a PCBA board packaging device, wherein the PCBA board packaging device comprises: a glue spraying assembly and a working table located below the glue spraying assembly; the glue spraying assembly is used for spraying PCBA board packaging UV glue liquid; the glue spraying assembly has a glue spraying panel on which a plurality of parallel spraying hole rows are distributed; each spraying hole row has a plurality of spraying holes through which spraying is controlled independently that are arranged in a first direction; the working table has a placement surface for placing a PCBA board;
the packaging method comprises controlling the glue spraying assembly to spray UV glue liquid to a target spraying area of the PCBA board by moving back and forth in a straight line in a horizontal direction.

30. The packaging method according to claim 29, wherein in the packaging method, the glue spraying assembly is positioned above the highest electronic element and the spacing between the glue spraying assembly and the highest electronic element is controlled to be less than 2 mm; relative height of the glue spraying assembly and a printed circuit board of the PCBA board is unchanged during the glue spraying process;
the packaging method comprises placing the PCBA board horizontally on a working table and controlling the glue spraying assembly to spray glue on the PCBA board on the working table in such a way that a spraying hole is vertically oriented toward the working table.

31. The packaging method according to claim 29, wherein during the glue spraying process, the glue spraying assembly is controlled to move back and forth in a horizontal straight line to spray UV glue liquid to the target spraying area of the PCBA board until the spraying package is completed.

32. The packaging method according to claim 29, further comprising: obtaining number of target spraying layers; wherein one spraying layer is formed by one linear one-way movement of the glue spraying assembly, and two spraying layers are formed by one linear round-trip movement;
controlling the glue spraying assembly to spray UV glue liquid to a target spraying area of the PCBA board by moving back and forth in a straight line in a horizontal direction until the target spraying area reaches the number of target spraying layers.

33. The packaging method according to claim 29, wherein the PCBA board has a positioning point; the glue spraying assembly is fixedly provided with a positioning portion for positioning the positioning point; the packaging method comprises:
placing the PCBA board horizontally on a working table; and
moving the glue spraying assembly and controlling the working table to move according to the positioning of the positioning point by the positioning portion until the PCBA board is located at the specified position;
curing the glue on the PCBA board while spraying the glue onto the PCBA board, wherein the position of the PCBA board is fixed during the glue curing process.

34. The packaging method according to claim 29, further comprising:
obtaining a glue spraying information picture carrying spraying area information; the glue spraying information picture is a bitmap;
identifying the spraying area information of the glue spraying information picture and obtaining the target spraying area of the PCBA board.

35. The packaging method according to claim 34, wherein the glue spraying information picture shows a spraying area by a predetermined color distinguished from base color, wherein a base color area is identified as a non-glue spraying area, a predetermined color area is identified as the target spraying area, and a distribution position of the predetermined color area relative to the base color area corresponds to a distribution position of the target spraying area on the PCBA board.
